(19) United States
(12) Patent Application Publication
(10) Pub. No.: US 2006/0290437 A1
(43) Pub. Date: Dec. 28, 2006

(54) RADIO APPARATUS

(75) Inventor: Atsushi Kimura, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/419,205

(22) Filed: May 19, 2006

(30) Foreign Application Priority Data
Jun. 27, 2005 (JP) 2005-186033

(51) Int. Cl. H03C 3/09

(52) U.S. Cl. 332/127

(57) ABSTRACT

A radio apparatus includes a PLL modulator outputting a signal whose frequency is modulated based on the voltage level of an input signal, a first switch to which a first signal having a predetermined frequency and a second signal are inputted, and which lets one of the first and second signals pass through depending on the presence of the second signal, a first filter that smoothes the first or second signal that has passed through the first switch and outputs the smoothed first or second signal to the PLL modulator, and a second switch that breaks a loop in the PLL modulator depending on the presence of the second signal.

### BACKGROUND OF THE INVENTION

1. Field of the Invention

The present invention relates to a radio apparatus which in particular has a PLL modulation circuit for forming an open loop at the time of data transmission.

2. Background Information

FIG. 1 shows a block diagram of a conventional FSK radio apparatus 900. As shown in FIG. 1, the FSK radio apparatus 900 has a low-pass filter 901 and a PLL (phase locked loop) modulation circuit 910. The PLL modulation circuit 910 has a VCO (voltage controlled oscillator) 911, a frequency divider 912, a clock oscillator 913, a phase comparator 914, and a loop filter 915.

In the structure shown in FIG. 1, a binary transmission data TXD which is composed of a combination of ‘0’s and ‘1’s is to be inputted to an input terminal IN. Here, the transmission data TXD is in the form of a rectangular wave. The transmission data TXD inputted to the input terminal IN will be inputted to the low-pass filter 901 as a signal s1. Upon receiving the signal s1 (i.e., the transmission data TXD), the low-pass filter 901 will let only low band frequency components in the signal s1 pass through as a signal s4.

Having passed through the low-pass filter 901, the signal s4 will be inputted to the VCO 911 in the PLL modulation circuit 910. Then, the VCO 911 will oscillate based on the voltage level of the signal s4 and the voltage level of a signal s10 (which will be described below) received from the loop filter 915, and output the resultant signal as a signal s5. The signal s5 outputted from the VCO 911 will diverge to reach the input of the frequency divider 912, and an output terminal OUT, where it will be outputted as the output of the PLL modulation circuit 910.

At the frequency divider 912, the inputted signal s5 will be divided by a preset dividing ratio n and outputted to the phase comparator 914 as a signal s6. To this phase comparator 914, a reference clock (i.e., a signal s7) outputted by the reference oscillator 913 will also be inputted. At the phase comparator 913, the phase of the signal s6 and the phase of the reference clock (i.e., the signal s7) will be compared, and a signal (i.e., a phase difference signal) s8, which is generated based on the resultant phase difference, will be outputted to the loop filter 915.

The loop filter 915 will take out DC components in the signal s8 (i.e., the phase difference signal), and output the resultant signal to the VCO 911 as a signal s9. In this way, a closed loop in the order of the VCO 911→the frequency divider 912→the phase comparator 914→the loop filter 915→the VCO 911 will be generated inside the PLL modulation circuit 910, and the center frequency of the signal s5 to be outputted from the PLL modulation circuit 910 will be adjusted to its target center frequency Fc [Hz].

However, the FSK radio apparatus 900 having such structure as described above is meant to be suitable for outputting an FSK modulation wave (i.e., the signal s5) from the VCO 911 of the PLL modulation circuit 910, by having the voltage (i.e., the signal s4) corresponding to the transmission data TXD inputted to the VCO 911 serve as a control voltage. Therefore, for instance, if transmission data TXD made up of consecutive identical values is inputted to the low-pass filter 901 as the signal s1, during this period, the voltage level of the signal s9 which is supposed to be outputted from the loop filter 915 will change toward the voltage level at the time the VCO 911 oscillates at the target center frequency Fc [Hz] due to the closed loop generated inside the PLL modulation circuit 910, and corresponding to such change, a problem may occur in which the center frequency of the signal s5, at which the VCO 910 is supposed to oscillate, will change.

One example of conventional technology that copes with such a problem is shown in Japanese Laid-Open Patent Application No. 7-154432 (hereinafter to be referred to as patent reference 1), for instance. According to the conventional technology of patent reference 1, when the same values are inputted consecutively for more than a predetermined period of time under the state in which a closed loop is being generated (hereinafter this state will be referred to as a closed loop state), the output voltage from the loop filter is adjusted for a predetermined period of time based on the reference clock from the reference oscillator in order to prevent the voltage level of the signal to be outputted from the loop filter from changing toward the voltage level at the time the VCO oscillates.

In the PLL modulation circuit described above, the operation of making the closed loop in the order of the VCO→the frequency divider→the phase comparator→the loop filter→the VCO at all times regardless of whether there is an input of transmission data TXD or not, and locking the center frequency of the signal at which the VCO is supposed to oscillate at the target center frequency Fc [Hz] based on an operation of the closed loop, has been conducted.

On the other hand, it is also possible to provide the PLL modulation circuit with a structure such that it can operate under a closed loop state when there is no input of transmission data TXD, and operate under an open loop state when there is an input of transmission data TXD.

In case of applying such structure, however, when the PLL modulation circuit is operating under the closed loop state, an oscillating frequency of the VCO in the PLL modulation circuit will be locked at the target center frequency Fc [Hz] in a state in which no transmission data TXD is input. Accordingly, there is a problem in that at the time when the transmission data TXD is inputted and the PLL modulation circuit starts operating under the open loop state, the center frequency of the signal at which the VCO is supposed to oscillate, i.e., the center frequency of a carrier (carrier wave), will deviate from the target center frequency Fc [Hz]. This is because the voltage under the closed loop state and the voltage under the open loop state will be different at the input of the VCO, and especially because the center voltage of the transmission data TXD will deviate at the input of the VCO under the closed loop state. In the following, such tendency will be described with reference to the drawings.

FIG. 2 is a block diagram showing the structure of an FSK radio apparatus 800 as a comparative example. The FSK radio apparatus 800 is configured such that a loop will open or close depending on the presence of transmission data TXD. FIG. 3 shows the signal wave of each signal in the FSK radio apparatus 800. In FIG. 2, with respect to the same structural elements as those in FIG. 1, the same reference numbers will be used, and detailed explanations of those structural elements will be omitted.

As shown in FIG. 2, the basic structure of the FSK radio apparatus 800 is the same as the FSK radio apparatus 900 shown in FIG. 1, except that the FSK radio apparatus 800 has a switch SW 815 that is added to the basic structure. The switch SW 815 is disposed in between the phase comparator 914 and the loop filter 915 in the PLL modulation circuit 810, and it is controlled to be switched ON/OFF based on a PLL control signal PLL-OFF inputted internally or externally. Here, the PLL control signal PLL-OFF will have its voltage level switched depending on the presence of transmission data TXD.

In this structure, in the initial state, there is no input of transmission data TXD (i.e., consecutive ‘0's), and therefore, the PLL control signal PLL-OFF will indicate High level, for instance. Thereby, the switch SW 815 will be in a closed state (i.e., an ON state), and a closed loop in the order of the VCO 911→the frequency divider 912→the phase comparator 914→the switch SW 815→the loop filter 915→the VCO 911 will be generated inside the PLL modulation circuit 810. Accordingly, the frequency of the signal s5 (i.e., the output signal) to be outputted from the PLL modulation circuit 810 will be locked at the target center frequency Fc [Hz] as shown in FIG. 3. In other words, the PLL modulation circuit 810 will be locked at the target center frequency Fc [Hz] while the signal s4 having passed through the low-pass filter 901 is in a state of 0V (i.e., in a state of having NULL data).

Next, as the PLL control signal PLL-OFF becomes Low level, the switch SW 815 will be switched OFF, and the loop inside the PLL modulation circuit 810 will break off. However, it should be noted that the PLL modulation circuit 810 operates while a certain time constant which prevents the frequency of the output signal (i.e., the signal s5) from changing immediately in response to the presence or absence of the transmission data TXD. Therefore, during a predetermined period of time from the point the internal loop broke off, the predetermined period of time being decided by the time constant, the PLL modulation circuit 810 will change the frequency of the output signal (i.e., the signal s5) based only on a voltage change of the signal s4 that has passed through the low-pass filter 901, i.e., based only on the voltage change of low frequency components in the transmission data TXD. Here, for instance, if ‘1’ is inputted as the transmission data TXD during this predetermined period of time, the PLL modulation circuit 810 will output the output signal (i.e., the signal s5) having a frequency Fc+2 df [Hz] which is higher than the target center frequency Fc [Hz] by 2 df [Hz]. The frequency 2 df [Hz] is determined by the voltage magnitude of the signal s4 received from the low-pass filter 901 and an electrical characteristic of the VCO 911.

Then, for instance, if serial data ‘01010101 . . . ’ is inputted as the transmission data TXD, the PLL modulation circuit 810 will output the signal s5 (i.e., the output signal) of which the center frequency is Fc+df [Hz], the maximum frequency is Fc+2 df [Hz] and the minimum frequency is Fc [Hz], as shown in FIG. 3. This means that the PLL modulation circuit 810 will output the output signal (i.e., the signal s5) which is in a frequency band to which an offset of df [Hz] is given, in addition to the target center frequency Fc [Hz]. This is because the PLL modulation circuit 810 is meant to output the output signal (i.e., the signal s5) which is frequency modulated based on the average voltage between a voltage level indicating ‘0’ data and a voltage level indicating ‘1’ data.

Thus, with respect to the conventional PLL modulation circuit, there is a problem in that the output signal is locked at the target frequency under the state in which there is no input of transmission data TXD, which makes it difficult to have a modulation signal having a center frequency equivalent to the target frequency outputted at the time when the status changes to that indicating that there is an input of transmission data TXD.

In view of the above, it will be apparent to those skilled in the art from this disclosure that there exists a need for an improved radio apparatus. This invention addresses this need in the art as well as other needs, which will become apparent to those skilled in the art from this disclosure.

### SUMMARY OF THE INVENTION

It is therefore an object of the present invention to resolve the above-described problems, and to provide a radio apparatus which is capable of adjusting the center frequency of a carrier (i.e., a carrier wave) to a target center frequency, and thereby capable of outputting a modulation wave of higher precision and higher quality.

In accordance with one aspect of the present invention, a radio apparatus comprises a PLL modulator, a first switch, a first filter, and a second switch. The PLL modulator outputs a signal having its frequency modulated based on the voltage level of an input signal. The first switch, to which a first signal having a predetermined frequency and a second signal are inputted, lets one of the first and second signals pass through, depending on the presence of the second signal. The first filter smoothes the first or second signal passed through the first switch and outputs the smoothed first or second signal to the PLL modulator. The second switch breaks a loop in the PLL modulator depending on the presence of the second signal.

In accordance with another aspect of the present invention, a radio apparatus comprises a PLL modulator, a duty ratio changing unit, a first switch, a first filter and a second switch. The PLL modulator outputs a signal having its frequency modulated based on a voltage level of an input signal. The duty ratio changing unit adjusts the duty ratio of a first signal having a predetermined frequency. The first switch, to which the first signal having the adjusted duty ratio and a second signal are inputted, lets one of the first and second signals pass through depending on the presence of the second signal. The first filter smoothes the first or second signal that has passed through the first switch, and outputs the smoothed first or second signal to the PLL modulator. The second switch breaks a loop in the PLL modulator depending on the presence of the second signal.

These and other objects, features, aspects, and advantages of the present invention will become apparent to those skilled in the art from the following detailed description, which, taken in conjunction with the annexed drawings, discloses preferred embodiments of the present invention.

### BRIEF DESCRIPTION OF THE DRAWINGS

Referring now to the attached drawings which form a part of this original disclosure:

FIG. 1 is a block diagram of a conventional FSK radio apparatus;

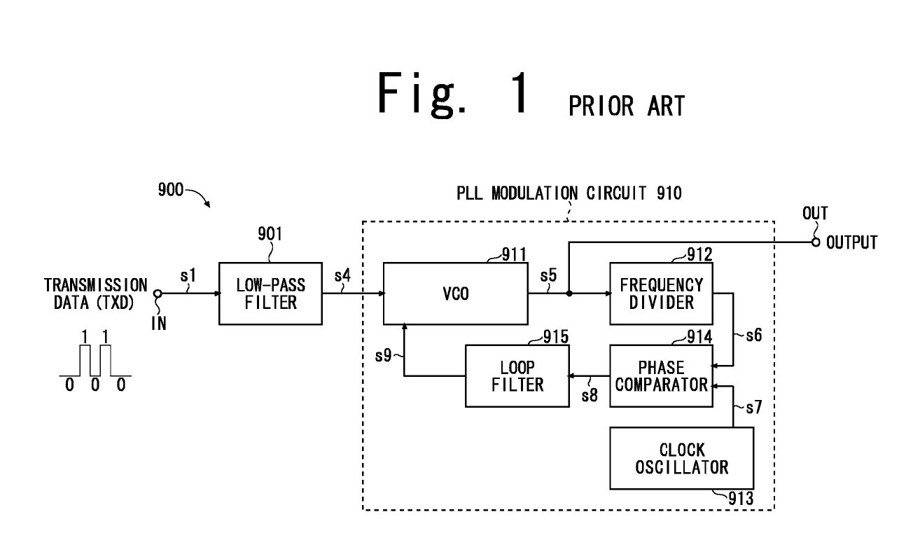

FIG. 2 is a block diagram showing a structure of an FSK (hereinafter to be referred to as GFSK) radio apparatus as a comparative example;

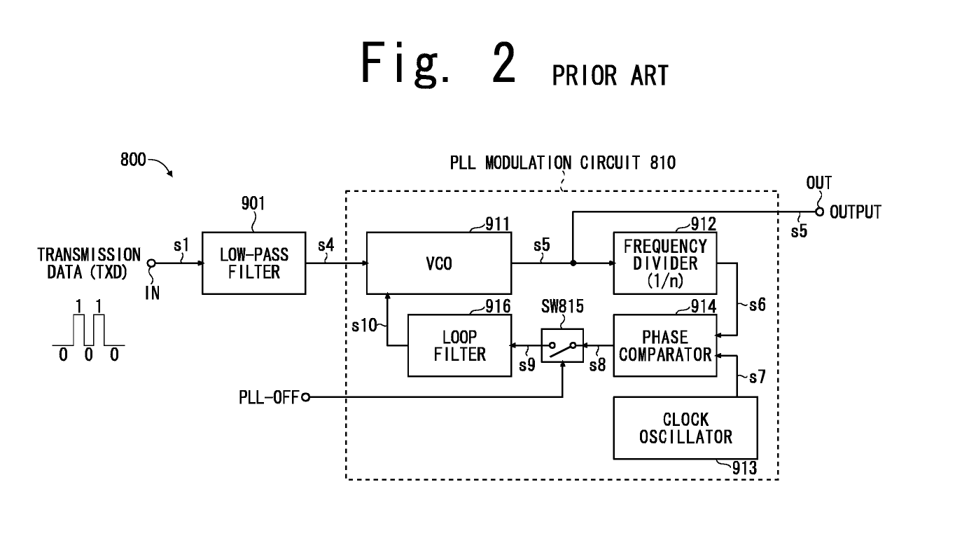

FIG. 3 is a signal waveform diagram of each signal in the FSK radio apparatus shown in FIG. 2;

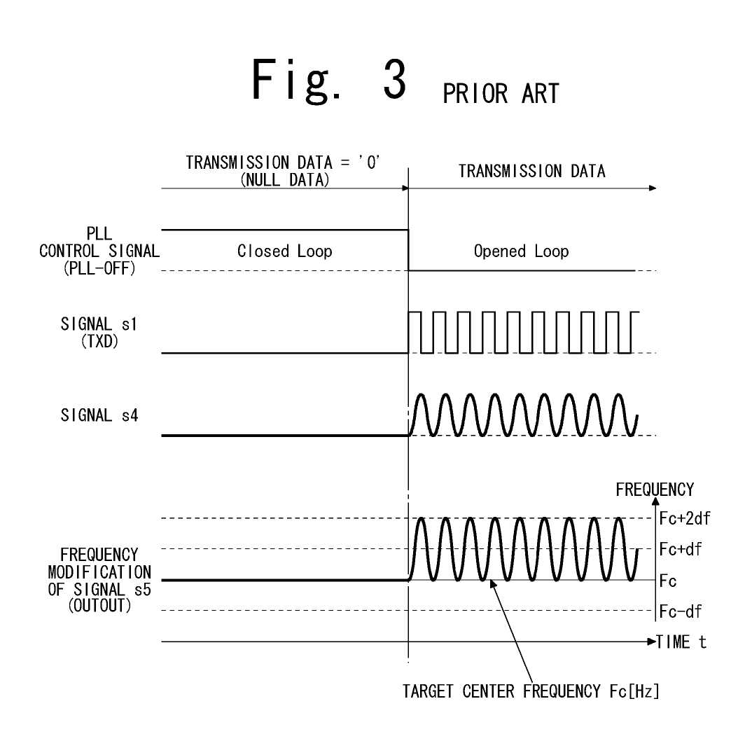

FIG. 4 is a schematic block diagram showing an outline structure of a Gaussian FSK radio apparatus according to a first embodiment of the present invention;

FIG. 5 is a signal waveform diagram of each signal in the Gaussian FSK radio apparatus according to the first embodiment of the present invention;

FIG. 6 is a table showing statuses of a switch SW 102 and a switch SW 115;

FIG. 7 is a signal waveform diagram of each signal in a Gaussian FSK radio apparatus according to a second embodiment of the present invention;

FIG. 8 is a schematic block diagram showing an outline structure of the GFSK radio apparatus according to the second embodiment of the present invention;

FIG. 9 is a signal waveform diagram of each signal in a Gaussian FSK radio apparatus according to a third embodiment of the present invention;

FIG. 10 is a table showing statuses of the switch SW 102 and the switch SW 115;

FIG. 11 is a schematic block diagram showing an outline structure of the GFSK radio apparatus according to the third embodiment of the present invention; and

FIG. 12 is a signal waveform diagram of each signal for generating the reference voltage Vref3 (i.e., the signal S15).

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

First, a first embodiment of the present invention will be described in detail with reference to the drawings.

Structure

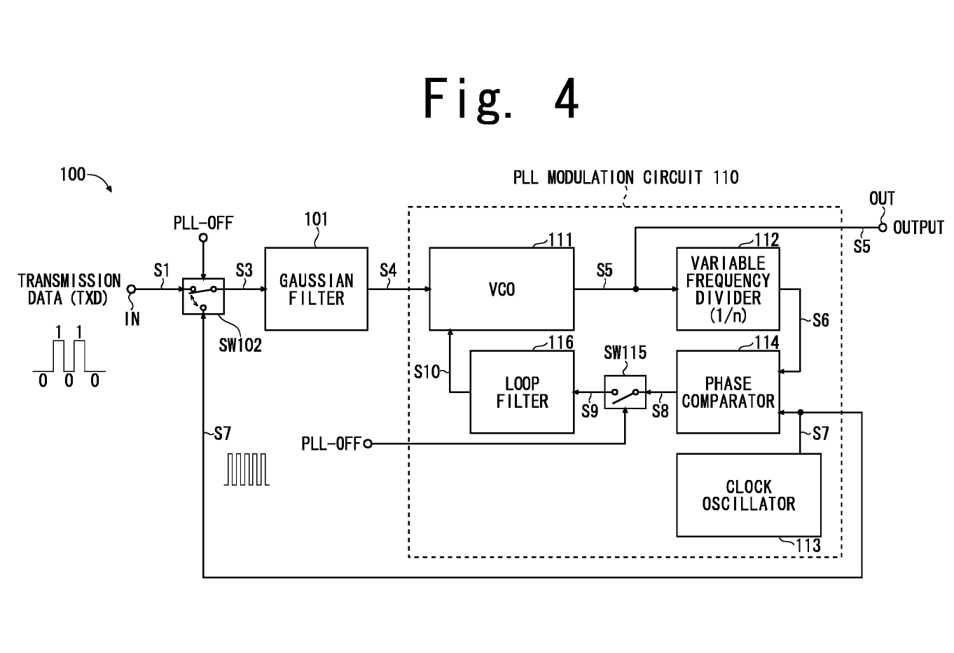

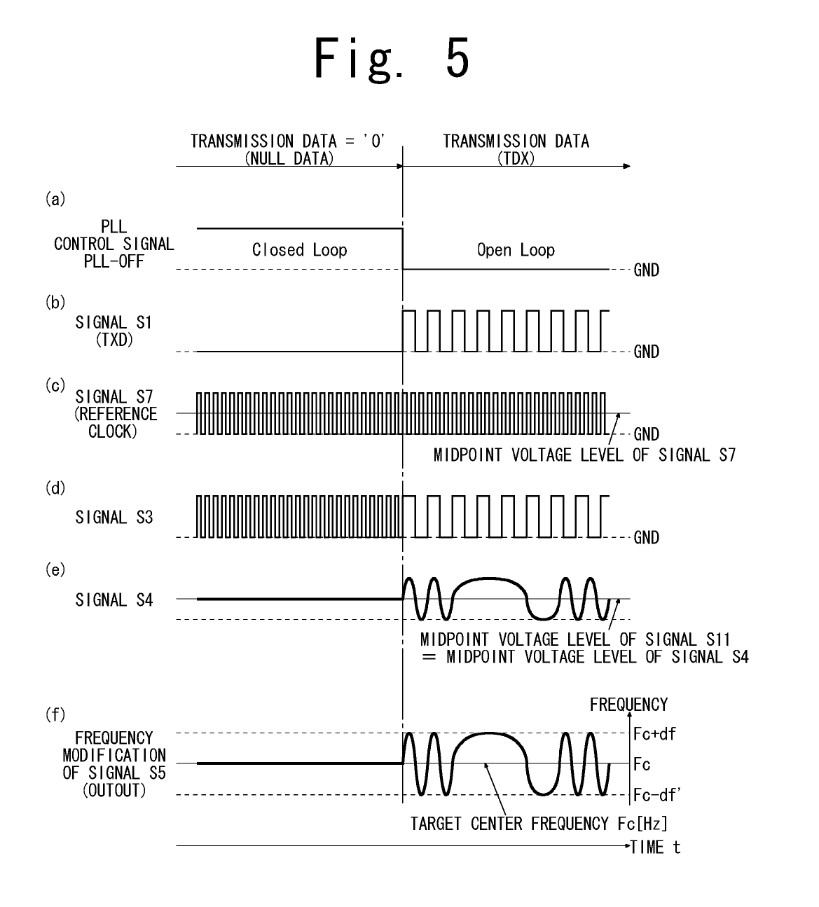

FIG. 4 is a schematic block diagram showing an outline structure of a Gaussian FSK (hereinafter to be referred to as GFSK) radio apparatus 100 according to the first embodiment of the present invention. FIG. 5(a) to FIG. 5(f) show waveforms of a PLL control signal PLL-OFF, signals S1 (i.e., TXD), S3, S4 and S7 (i.e., reference clock), and the frequency change of a signal S5 (i.e., an output signal) taken along a time axis, respectively.

As shown in FIG. 4, the GFSK radio apparatus 100 has a Gaussian filter (i.e., a first filter) 101, a switch (first switch) SW 102, and a PLL modulation circuit (i.e., a PLL modulator) 110. The PLL modulation circuit 110 includes a VCO 111, a variable frequency divider (1/n) 112, a reference oscillator 113, a phase comparator 114, a switch (second switch) SW 115, and a loop filter (i.e., a second or third filter) 116.

In the structure shown in FIG. 4, transmission data TXD (q.v. FIG. 5(b)) made up of a combination of ‘0’s and ‘1’s will be inputted to an input terminal IN. Here, the transmission data TXD is in the form of a rectangular wave.

The transmission data TXD inputted to the input terminal IN will be inputted to one of two input terminals of the switch SW 102, which is a two-input one-output switch, as a signal S1 (i.e., a second signal). To the other input terminal of the switch SW 102, a reference clock (q.v. FIG. 5(c)) will be inputted from the reference oscillator 113, which will be described below, as a signal S7 (i.e., a first signal). Here, the signal S7 is fixed to a predetermined frequency. Moreover, a PLL control signal PLL-OFF (q.v. FIG. 5(a)) is to be inputted to a control terminal of the switch SW 102. The PLL control signal PLL-OFF is a signal which can have its voltage level switched to High level or Low level depending on the presence of the transmission data TXD, and it is generated at an external circuit which is not shown. In the present invention, however, it is also possible to have an additional structure which can detect the presence of the transmission data TXD and change the voltage level of the PLL control signal PLL-OFF accordingly, inside the GFSK radio apparatus 100. This additional structure may be a detecting unit or a detecting means.

Upon receiving the PLL control signal PLL-OFF, the switch SW 102 will switch between the two input terminals for connecting to the output terminal based on the received PLL control signal PLL-OFF, and output a selected signal (i.e., the signal S1 or S7) to the Gaussian filter 101 in the following stage as a signal S3 (q.v. FIG. 5(d)).

The Gaussian filter 101 is a filter for integrating (or smoothing) a signal inputted thereto to let low frequency components of the signal pass through. Accordingly, the signal S3 inputted to the Gaussian filter 101 will be integrated (or smoothed) based on a time constant having been set to the Gaussian filter 101, and outputted as a signal S4 (i.e., the smoothed first signal or second signal) as shown in FIG. 5(e). The time constant having been set to the Gaussian filter 101 should be set to a value that can be used to convert the reference clock (i.e., the signal S7) to have a voltage level at a midpoint (or an average) between a maximum voltage level and a minimum voltage level of the reference clock, and to transform the rectangular wave inputted as the transmission data TXD (i.e. the signal S1) to a waveform approximating a sine wave (or a Gaussian curve). Explaining this in terms of frequency, the frequency of the reference clock (i.e. the signal S7) is set to a sufficiently high frequency as compared to a cut-off frequency of the Gaussian filter 101. Here, the ‘sufficiently high frequency’ indicates a frequency (e.g. a frequency greater than 10 MHz) which is greater than about 20 times the 3 dB cut-off frequency (e.g. 500 kHz), for instance.

The signal S4 outputted from the Gaussian filter 101 will be inputted to the VCO 111 in the PLL modulation circuit 110. The VCO 111 is an oscillator which oscillates at a frequency decided based on an impressed voltage and its electrical characteristic. Accordingly, the VCO 111 will oscillate at a frequency decided based on the voltage level of the inputted signal S4, the voltage level of a signal S10 (i.e., the smoothed fourth signal) received from the loop filter 116 (which will be described later on) and its electrical characteristic, and output the resultant signal as a signal S5 (i.e., a third signal) which changes its frequency in a manner as shown in FIG. 5(f).

The signal S5 outputted from the VCO 111 will then be outputted from an output terminal OUT as an output signal, and at the same time will be inputted to the variable frequency divider 112. The variable frequency divider 112 is a kind of frequency divider which is capable of changing a dividing ratio ‘n’. This variable frequency divider 112 will frequency-divide the inputted signal S5 based on the dividing ratio ‘n’ in order to enable the phase comparator 114 in the following stage to detect a phase deviation of the signal S5 on the basis of the reference clock (i.e., the signal S7) received from the reference oscillator 113, and output the resultant signal as a signal S6 (i.e., the smoothed third signal). The dividing ratio ‘n’ having been set to the variable frequency divider 112 should be a dividing ratio which enables the frequency of the signal S6, which is supposed to be outputted from the variable frequency divider 112 at the time when the reference clock (i.e., the signal S7) is selected as the signal S3, to become equal to the frequency of the reference clock (i.e., the signal S7). Here, it is also possible to use a frequency divider having a fixed dividing ratio In’ instead of the variable frequency divider 112. In this case, however, a carrier frequency of the output signal (i.e., the signal S5) will be limited to one frequency.

The signal S6 outputted from the variable frequency divider 112 will be inputted to one of the two inputs of the phase comparator 114. In the meantime, to the other terminal of the phase comparator 114, the reference clock from the reference oscillator 113 as described above will be inputted as the signal S7. The phase comparator 114 is a circuit for detecting a phase difference between these two inputted signals, based on the difference in the rising edge between the two signals. Accordingly, the phase comparator 114 will detect the phase difference between the inputted signal S6 (i.e., the frequency-divided signal S5 (the output signal)) and the signal S7 (i.e., the reference clock) based on the rising edge of each signal to generate a signal S8 (i.e., a phase difference signal/a fourth signal).

The signal S8 (i.e., the phase difference signal) generated at the phase comparator 114 will be inputted to an input terminal of the switch SW 115 provided inside the PLL modulation circuit 110. In the meantime, the PLL control signal PLL-OFF will be inputted to the control terminal of the switch SW 115, as in the case of the above-described switch SW 102. Based on the received PLL control signal PLL-OFF, the switch SW 115 will switch in order to let the signal S8 (i.e., the phase difference signal) pass or not pass through. In this way, a loop generated inside the PLL modulation circuit 110 can be controlled to be open or closed.

An output terminal of the switch SW 115 is connected to an input of the loop filter 116. Therefore, when the switch SW 115 is turned ON (i.e., the PLL control signal PLL-OFF is at High level), the signal S8 (i.e., the phase difference signal) will be inputted to the loop filter 116 as a signal S9. On the other hand, when the switch SW 115 is turned OFF (i.e., the PLL control signal PLL-OFF is at Low level), the signal S9 will not be inputted to the loop filter 116. In other words, this can be thought of as a signal at Low level (i.e., 0V) being inputted to the loop filter 116 as the signal S9.

The loop filter 116 is a low-pass filter for converting an inputted signal to a DC signal with less AC components by smoothing the inputted signal. Moreover, this loop filter 116 also serves to determine the transmission characteristic for enabling stable control of a loop generated inside the PLL modulation circuit 110. The loop filter 116 will output the DC components taken out from the signal S9 as a signal S10. Therefore, when the PLL control signal PLL-OFF is at High level and when a closed loop is generated inside the PLL modulation circuit 110, the loop filter 116 will smooth the phase difference signal (i.e., the signal S9) and output it to the VCO 111 as a control signal (i.e., the signal S10). However, when the PLL control signal PLL-OFF is at Low level, the loop filter 116 will not output the control signal (i.e., the signal S10) to the VCO 111. In other words, this a control signal at Low level will be outputted to the VCO 111.

In this way, in the GFSK radio apparatus 100 according to the first embodiment of the present invention, when there is no input of transmission data TXD, the switch SW 102 will select the reference clock (i.e., the signal S7) while the switch SW 115 turns ON, generating a closed loop inside the PLL modulation circuit 110. Thereby, the frequency of the signal S5 outputted from the PLL modulation circuit will be locked at a target center frequency Fc [Hz] on the basis of the midpoint voltage level of the reference clock (i.e., the signal S7). On the other hand, when there is an input of transmission data TXD, the switch SW 102 will select the transmission data TXD (i.e., the signal S1) while the switch SW 115 will turn OFF, cutting off the loop inside the PLL modulation circuit 110. However, it should be noted that in this embodiment, the PLL modulation circuit 110 operates while having a certain time constant which prevents the frequency of the signal S5 to be outputted from changing immediately in response to the presence or absence of the transmission data TXD. Therefore, the PLL modulation circuit 110 will output the signal S5 which has the target center frequency Fc [Hz], having been looked at at the time of closed loop operation, as the center frequency of a carrier (also called a carrier wave), and which is frequency-modulated based on the transmission data TXD (the signal S4 having passed through the Gaussian filter 101 to be exact).

In this embodiment, the signal S7 (i.e., the reference clock) outputted from the reference oscillator 113 will be inputted to the Gaussian filter 101 through the switching operation of the switch SW 102. Accordingly, it is not necessary to adopt a separate structure (e.g. a different reference oscillator etc.) for generating a voltage for oscillating the VCO 111 at the target center frequency Fc [Hz]. This means that the frequency to be locked by the PLL modulation circuit 110 at the time when there is no input of transmission data TXD, i.e., at the time when operating under a closed loop state, will be controlled by the midpoint voltage of the signal S7 (i.e., the reference clock). Therefore, according to this embodiment, it is possible to set the VCO 111 and the reference oscillator 113 such that the VCO 111 may oscillate at the target center frequency Fc [Hz] when the midpoint voltage of the reference clock (i.e., the signal S7) is impressed.

Operation

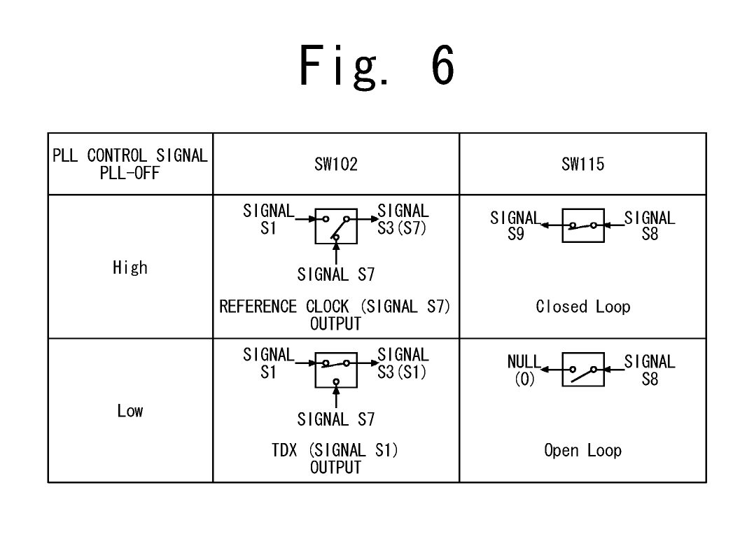

Now, the operation of the GFSK radio apparatus 100 according to the first embodiment of the present invention will be described in detail with reference to FIG. 4, FIG. 5 and FIG. 6. FIG. 6 is a table showing statuses of the switch SW 102 and the switch SW 115 with respect to different voltage levels of the PLL control signal PLL-OFF.

In the initial state, as shown in FIG. 5(a) and FIG. 5(b), there is no input of transmission data TXD (i.e., consecutive ‘0’s), and the PLL control signal PLL-OFF indicates High level, for instance. Accordingly, as shown in the upper row (High level) of the table in FIG. 6, the switch SW 102 will select the reference clock (i.e., the signal S7) and the switch SW 115 will be in a closed state (i.e., the switch SW 115 will turn ON). Thereby, as shown in FIG. 5(e), the midpoint voltage of the reference clock (i.e., the signal S7) will be impressed to the VCO 111 and a closed loop in the order of the VCO 111→the variable frequency divider 112→the phase comparator 114→the switch SW 115→the loop filter 116→the VCO 111 will be generated inside the PLL modulation circuit 110.

The signal S4 at the midpoint voltage level of the reference clock (i.e., the signal S7) will be inputted to the VCO 111 in the PLL modulation circuit 110. At this time, the closed loop as mentioned above is being generated inside the PLL modulation circuit 110. Therefore, the signal S10 outputted from the loop filter 116 will also be inputted to the VCO 111. The signal S10 is a signal which is generated by having the signal S8 (i.e., the phase difference signal) smoothed at the loop filter 116, the signal S8 having been generated based on a phase difference between the signal S6, which has been generated by having the signal S5 outputted from the VCO 111 frequency-divided by the predetermined dividing ratio ‘n’, and the reference clock (i.e., the signal S7) outputted from the reference oscillator 113. Accordingly, the VCO 111 which is supposed to oscillate at a frequency determined by the signal S4, the signal S10 and its electrical characteristic, will operate such that the phase difference signal (i.e., the signal S8) will become ‘0’, i.e., such that the phases of the signal S6 from the frequency divider 112 and the reference clock (i.e., the signal S7) will become equal, and thereby, the signal S5 (i.e., the output signal) to be outputted from the PLL modulation circuit 110 will be locked at the target center frequency Fc [Hz].

Next, as shown in FIG. 5(a), when the PLL control signal PLL-OFF becomes Low level, the switch SW 115 will be in an open state (i.e., the switch SW 115 will turn OFF), the loop inside the PLL modulation circuit will be cut off and the switch SW 102 will select the transmission data TXD (i.e., the signal S1), as shown in the lower row (Low level) of the table in FIG. 6. However, as described above, the PLL modulation circuit 110 operates while having a certain time constant which prevents the frequency of the output signal (i.e., the signal S5) to be outputted from changing immediately in response to the presence or absence of the transmission data TXD. Therefore, as shown in FIG. 5(f), for a certain period of time from the point the internal loop is cut off, this period of time being determined by the time constant, the PLL modulation circuit 110 will change the frequency of the output signal (i.e., the signal S5) based only on the voltage change of the signal S4 that has passed through the Gaussian filter 101, i.e., the voltage change of the smoothed transmission data TXD.

Here, if ‘1’ data is inputted as the transmission data TXD during this certain period of time, the PLL modulation circuit 110 will output the output signal (i.e., the signal S5) having a frequency Fc+df [Hz] which is higher than the target center frequency Fc [Hz] by df [Hz]. The frequency df [Hz] is determined by a voltage magnitude of the signal S4 received from the Gaussian filter 101 and an electrical characteristic of the VCO 111.

Then, for instance, if serial data ‘01010101 . . . ’ is inputted as the transmission data TXD, the PLL modulation circuit 110 will output the signal S5 (i.e., the output signal) of which the center frequency is Fc [Hz], the maximum frequency is Fc+df [Hz] and the minimum frequency is Fc−df [Hz], as shown in FIG. 5(f). This means that the PLL modulation circuit 110 will output the signal S5 having a center frequency Fc [Hz].

As described above, according to the first embodiment of the present invention, when there is no input of transmission data TXD (i.e., the signal S1), the frequency clock (i.e., the signal S7), having been fixed to a predetermined frequency, will be smoothed and inputted to the PLL modulation circuit 110. Therefore, it becomes possible to let the frequency at which the PLL modulation circuit 110 is supposed to lock at the time when there is no reference clock (i.e., the signal S7) become the target frequency that is determined by the voltage level (e.g. the midpoint voltage level) obtained from the reference clock (i.e., the signal S7). Thus it becomes possible to control the center frequency at the time when there is a status change indicating that there is an input of transmission data TXD (i.e., the signal S1) that will become the target center frequency Fc [Hz]. In other words, according to this embodiment, it is possible to adjust the center frequency of the output signal (i.e., the signal S5) outputted from the PLL modulation circuit 110, i.e., the center frequency of a carrier (i.e., a carrier wave), to the target center frequency Fc [Hz], and generate a transmission waveform having the same modulation width in the positive side and in the negative side. Thereby, it becomes possible to output a modulation wave with higher precision and quality.

### Second Embodiment

Now, a second embodiment of the present invention will be described in detail with reference to the drawings. In the following description, the same reference numbers will be used with respect to the same structural elements as those in the first embodiment, and a detailed explanation of those structural elements will be omitted.

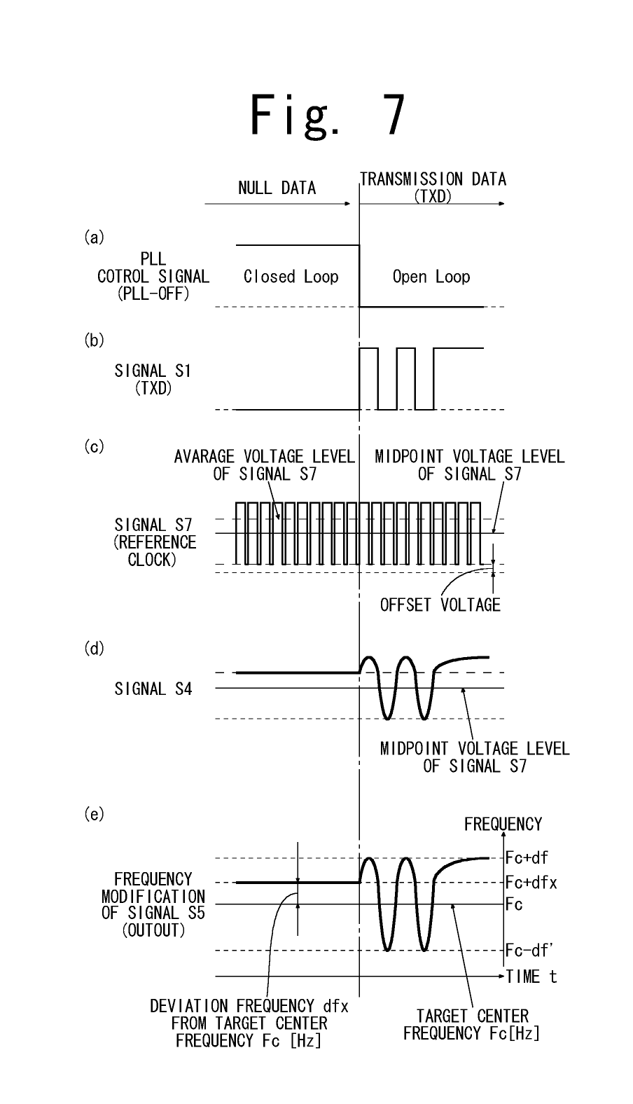

In the GFSK radio apparatus 100 according to the first embodiment, at the time when there is no input of transmission data TXD, the midpoint voltage of the reference clock (i.e., the signal S7) outputted from the reference oscillator 113 is used to adjust the signal S5 (i.e., the output signal) outputted from the PLL modulation circuit 110 to the target center frequency Fc [Hz] at the time when there is no input of transmission data TXD. However, as shown in FIG. 7(c), when the duty ratio of the reference clock (i.e., the signal S7) happens to deviate from a desired value (e.g. 50%), or when an offset voltage happens to be superimposed onto the reference clock (i.e., the signal S7), the voltage level of the reference clock (i.e., the signal S4) having passed through the Gaussian filter 101 will deviate upwardly or downwardly from the midpoint voltage level of the reference clock (i.e., the signal S7) as shown in FIG. 7(d).

Therefore, as shown in FIG. 7(e), under the state in which there is no input of transmission data TXD, there might be a situation in which the frequency of the output signal (i.e., the signal S5) outputted from the PLL modulation circuit 110 becomes locked at a frequency Fc+fdx [Hz] which deviates from the target center frequency Fc [Hz] by dfx [Hz]. Here, the frequency df [Hz] is determined by the difference in the voltage level of the signal S4 with respect to the midpoint voltage level of the reference clock (i.e., the signal S7) and an electrical characteristic of the VCO 111.

In this case, because the PLL modulation circuit 110 is structured to operate while having the predetermined time constant, when the transmission data TXD (i.e., the signal S1) as shown in FIG. 7(b) is inputted after the PLL control signal PLL-OFF became Low level as shown in FIG. 7(a), for instance, the PLL modulation circuit 110 may output a modulation wave, which takes the frequency Fc+fdx [Hz] as a carrier, as the signal S5.

Considering these points, the second embodiment of the present invention is structured to enable the locking frequency to be adjusted to the target center frequency Fc [Hz] even when the duty ratio of the reference clock (i.e., the signal S7) happens to deviate from a desired value or when an offset voltage happens to be superimposed onto the reference clock (i.e., the signal S7). In the following description, it is assumed that the duty ratio of the reference clock (i.e., the signal S7) is not the desired value 50%.

Structure

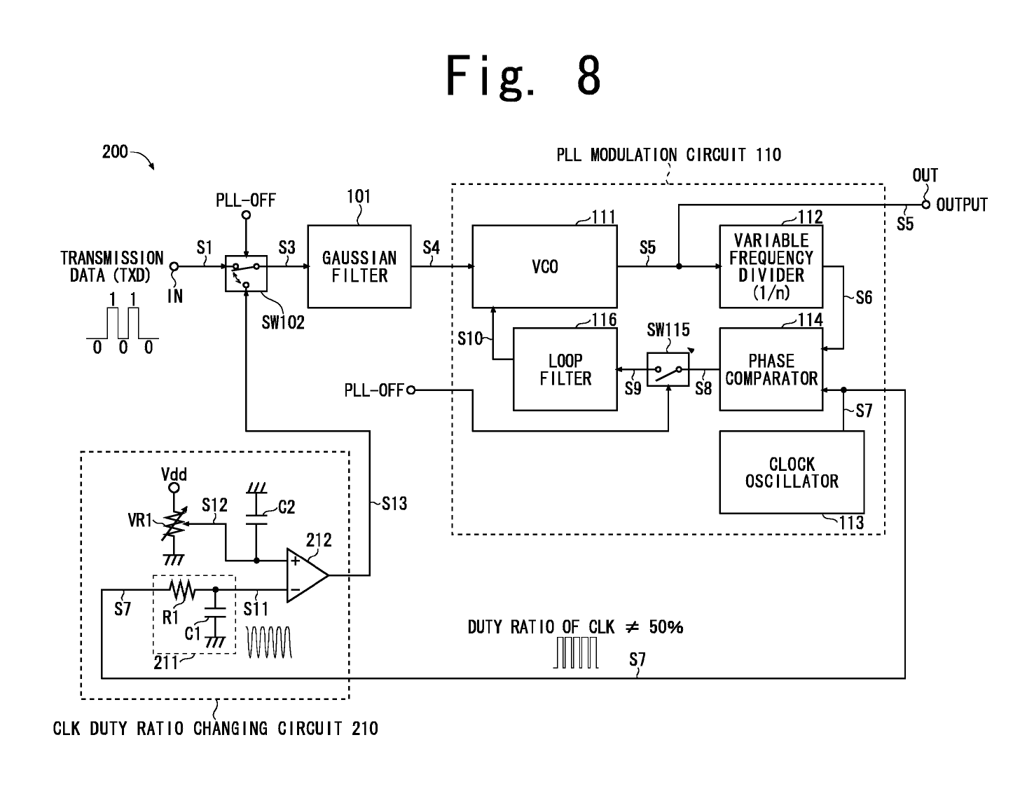

FIG. 8 is a schematic block diagram showing an outline structure of a GFSK radio apparatus 200 according to the second embodiment of the present invention.

As can been seen from FIG. 8, the basic structure of the GFSK radio apparatus 200 is the same as the GFSK radio apparatus 100 according to the first embodiment, except that the GFSK radio apparatus 200 has a CLK duty ratio changing circuit (i.e., a duty ratio adjusting unit) 210 that is added to the basic structure.

In the structure shown in FIG. 8, the CLK duty ratio changing circuit 210 has a low-pass filter (i.e., a second filter) 211, a variable resistance (i.e., a reference voltage output unit) VR1, a comparator (i.e., a comparing unit) 212 and a bypass capacitor C2.

The low-pass filter 211 is made up of a resistance R1 and a capacitor C1. The resistance R1 is disposed between the reference oscillator 113 in the PLL modulation circuit 110 and one of the two input terminals (i.e., an inverting input terminal) of the comparator 212 in series, and the capacitor C1 is disposed between a latter stage of the resistance R1 and a ground GND. The low-pass filter 211 will let low frequency components of the reference clock (i.e., the signal S7) inputted thereto pass through, based on a time constant determined by the resistance R1 and the capacitor C1, to be outputted to the inverting input terminal of the comparator 212 as a signal S11 (i.e., the first signal transformed into a waveform that is the same as or approximating a sine wave). In the low-pass filter 211, values of the resistance R1 and the capacitor C1 are set, for instance, to have a 3 dB cut-off frequency with respect to the reference clock (i.e., the signal S7). That is, the values of the resistance R1 and the capacitor C1 are being set such that the reference clock (i.e., the signal S7) in the form of a rectangular wave can be transformed to have a waveform approximating a sine wave.

The variable resistance VR1 is disposed between a power supply voltage Vdd and the ground GND, and its adjustment terminal for adjusting a resistance value of the variable resistance VR1 is connected to the other input terminal (i.e., a non-inverting input terminal) of the comparator 212. Therefore, the variable resistance VR1 will input a voltage according to its adjusted resistance value to the non-inverting input terminal of the comparator 212 as a reference voltage Vref1 (i.e., a signal S12/a first reference voltage). Here, it is desirable that the power supply voltage Vdd is higher than the maximum voltage of the reference clock (i.e., the signal S7). However, it is appropriate as long as the power supply voltage Vdd is at least higher than a predictable maximum average voltage of the reference clock (i.e., the signal S7). The bypass comparator C2 for noise rejection is connected between the non-inverting input terminal of the comparator 212 and the ground GND, and by means of this bypass comparator C2, high frequency noises can be removed.

The comparator 212 will compare voltage levels of the signal S11 and the signal S12 (i.e., the reference voltage Vref1) inputted thereto in the above described way, and output the comparison result as a signal S13 (i.e., the first signal having its duty ratio being adjusted). At this time, by adjusting the resistance value of the variable resistance VR1, it becomes possible to adjust the duty ratio of the signal S13 to 50%.

The signal S13 outputted from the comparator 212 will be inputted to one of the two input terminals of the switch SW 102 in place of the signal S7 (i.e., the reference clock) in the case of the first embodiment. Accordingly, on the basis of the PLL control signal PLL-OFF, the switch SW 102 will select between the signal S13 and the signal S1 (i.e., the transmission data TXD) for output, and output the selected signal to the Gaussian filter 101 as the signal S3.

The rest of the structure of the GFSK radio apparatus 200 is the same as the GFSK radio apparatus 100 according to the first embodiment, and therefore, a detailed description thereof will be omitted here.

Operation

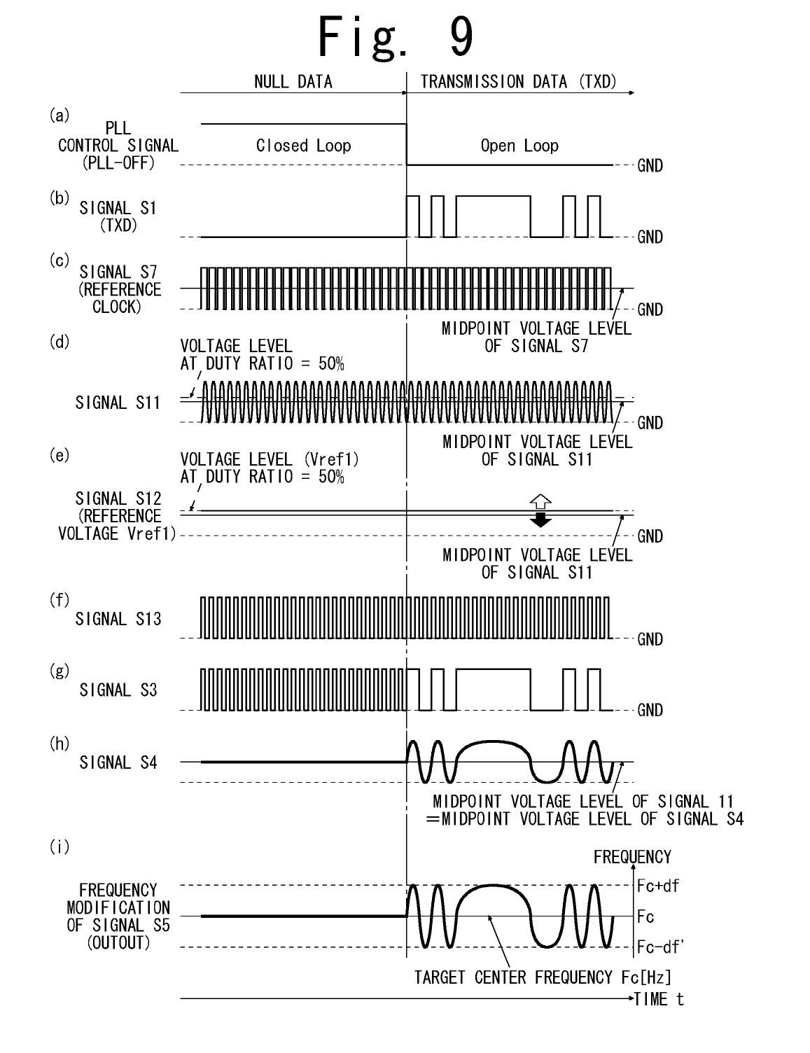

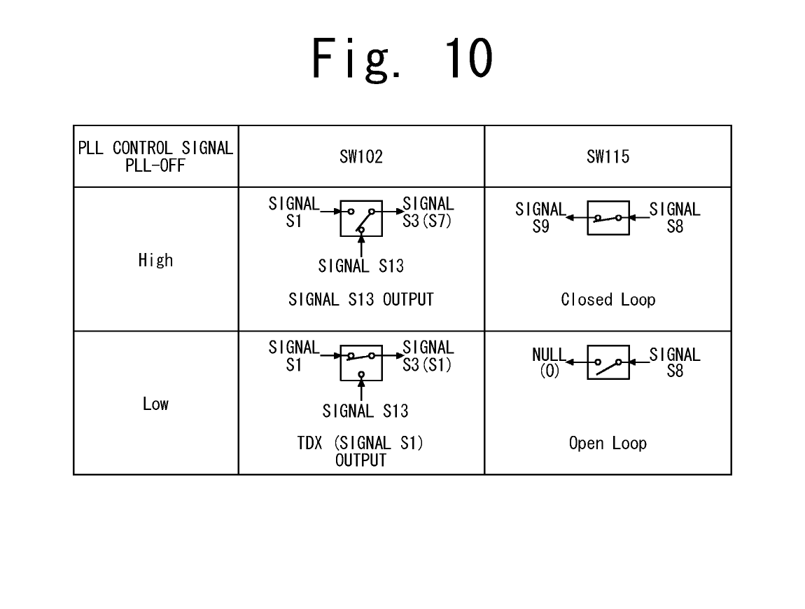

Now, the operation of the GFSK radio apparatus 200 according to the second embodiment of the present invention will be described in detail with reference to FIG. 8, FIG. 9 and FIG. 10. FIG. 8(a) to FIG. 8(i) show waveforms of the PLL control signal PLL-OFF, the signals S1 (i.e., the TXD), S4, S7 (i.e., the reference clock), s11, S12 and S13, and a frequency change of the signal S5 (i.e., the output signal) taken along a time axis, respectively. FIG. 10 is a table showing statuses of the switch SW 102 and the switch SW 115 with respect to different voltage levels of the PLL control signal PLL-OFF.

Operation of Adjusting Duty Ratio of Signal S13

First, the operation of adjusting the duty ratio of the signal S13, which is to be inputted to the Gaussian filter 101 via the switch SW 102 to the desired 50%, will be described with reference to the drawings.

As shown in FIG. 8, the reference clock (i.e., the signal S7) outputted from the reference oscillator 113 will be inputted to the CLK duty ratio changing circuit 210. At this time, however, as shown in FIG. 9(c), the duty ratio of the inputted reference clock (i.e., the signal S7) is not 50%.

The reference clock (i.e., the signal S7) inputted to the CLK duty ratio changing circuit 210 will first have its waveform transformed from a rectangular wave to a waveform approximating a sine wave as shown in FIG. 9(d), and inputted to the inverting input terminal of the comparator 212 as the signal S11.

In the meantime, to the non-inverting input terminal of the comparator 212, a voltage level (i.e., the signal S12) that has been voltage-divided and adjusted by the variable resistance VR1 will be inputted as the reference signal Vref 1. This signal S12 (i.e., the signal S12) is a signal indicating the voltage level according to the adjusted resistance value as described above. For instance, by adjusting the resistance value of the variable resistance VR1 in an upward direction, the voltage level of the signal S12 (i.e., the reference voltage Vref1) will be adjusted in a downward direction, as shown by a downward arrow in FIG. 9(e). On the other hand, by adjusting the resistance value of the variable resistance VR 1 in a downward direction, for instance, the voltage level of the signal S12 (i.e., the reference voltage Vref1) will be adjusted in an upward direction, as shown by an upward arrow in FIG. 9(e). This signal S12 (i.e., the reference voltage Vref1) will be used as a reference voltage level at the time of generating the signal S13 with a duty ratio of 50%.

The comparator 212 will slice the inputted signal S11 by the reference voltage Vref1 (i.e., the signal S12) in order to generate the signal S13 which is in the form of a rectangular wave having a duty ratio of 50%, and output the signal S13 to the switch SW 102. Here, the expression ‘slicing the inputted signal S11 by the reference voltage Vref1’ suggests an operation of outputting High level (i.e., a first voltage level) when the signal S11 has a higher voltage level than the reference voltage Vref1 (i.e., the signal S12) or outputting Low level (i.e., a second voltage level) when the signal S11 has a lower voltage level than the reference voltage Vref1 (i.e., the signal S12).

In this way, by slicing the signal S11 having a waveform approximating a sine wave by the adjustable reference voltage Vref1, the comparator 212 can output the signal S13 that is adjusted to have a duty ratio of 50% as shown in FIG. 9(f). For instance, when the voltage level of the signal S12 (i.e., the reference voltage Vref1) is adjusted in a downward direction by letting the resistance value of the variable resistance VR1 change to a considerable extent, the duty ratio of the signal S13 will become large. On the other hand, when the voltage level of the signal S12 (i.e., the reference voltage Vref1) is adjusted in an upward direction by letting the resistance value of the variable resistance VR1 change to a small extent, for instance, the duty ratio of the signal S13 will become small. In this embodiment, it is possible to adopt a structure such that the operation of adjusting the resistance value of the variable resistance VR 1 can be done manually. Moreover, in this embodiment, the duty ratio of the signal S13 does not necessarily have to be 50%, but it can also be adjusted to another desired duty ratio.

Basic Operation

Now, the basic operation of the GFSK radio apparatus 200 for locking at the desired center frequency Fc [Hz] and generating a modulation wave with the desired center frequency Fc [Hz] will be described with reference to the drawings.

In the initial state, as shown in FIG. 9(a) and FIG. 9(b), there is no input of transmission data TXD (i.e., consecutive ‘0’s), and the PLL control signal PLL-OFF indicates High level, for instance. Accordingly, as shown in the upper row (High level) of the table in FIG. 10, the switch SW 102 will select the reference clock (i.e., the signal S7), and the switch SW 115 will be in a closed state (i.e., the switch SW 115 will turn ON). Thereby, as shown in FIG. 9(h), the midpoint voltage of the signal S13 (i.e., the midpoint voltage of the reference clock (i.e., the signal S7)), the signal S13 being adjusted to have a duty ratio of 50%, will be impressed to the VCO 111, and a closed loop in the order of the VCO 111→the variable frequency divider 112→the phase comparator 114→the switch SW 115→the loop filter 116→the VCO 111 will be generated inside the PLL modulation circuit 110.

Here, when the signal S13 is selected by the switch SW 102, as described earlier, the Gaussian filter 101 will smooth the signal S13, and output the signal S4 (i.e., the first signal having been smoothed and having its duty ratio adjusted) which is predetermined and has the midpoint voltage level of the signal 13 (q.v. FIG. 9(h)). Accordingly, when the reference voltage of the variable resistance VR1 is adjusted to a considerable extent in order to make the duty ratio of the signal S13 large, for instance, the voltage level of the signal S4 will rise. As a result, the oscillating frequency of the VCO 111 (i.e., the frequency of the signal S5), which will be described below, will become high. On the other hand, when the reference voltage of the variable resistance VR1 is adjusted to a small extent in order to make the duty ratio of the signal S13 small, for instance, the voltage level of the signal S4 will drop. As a result, the oscillating frequency of the VCO 111 (i.e., the frequency of the signal S5) will become low.

The signal S4 having the midpoint voltage level of the signal S13 is inputted to the VCO 111 in the PLL modulation circuit 110 as a control voltage. At this time, as described earlier, a closed loop is generated inside the PLL modulation circuit 110. Therefore, the signal S10 outputted from the loop filter 116 will also be inputted to the VCO 111. The signal S10 is a signal which is generated by having the signal S8 (i.e., the phase difference signal) smoothed at the loop filter 116, the signal S8 having been generated based on the phase difference between the signal S6, which has been generated by having the signal S5 outputted from the VCO 111 frequency-divided by the predetermined dividing ratio ‘n’, and the reference clock (i.e., the signal S7) outputted from the reference oscillator 113. Accordingly, the VCO 111, which is supposed to oscillate at a frequency determined by the signal S4, the signal S10, and its electrical characteristic, will operate such that the phase difference signal (i.e., the signal S8) will become ‘0’, i.e., such that the phase of the signal S6 outputted from the frequency divider 112 and the phase of the reference clock (i.e., the signal S7) will become equal to each other. Thereby, the signal S5 (i.e., the output signal) to be outputted from the PLL modulation circuit 110 will be locked to the target center frequency Fc [Hz].

The operation of the GFSK radio apparatus 200 at the time when the PLL control signal PLL-OFF becomes Low level, i.e., the operation at the time when there is an input of transmission data TXD, is the same as in the first embodiment, and therefore, a detailed description thereof will be omitted here.

As described above, the second embodiment of the present invention adopts a structure in which, when there is no input of transmission data TXD (i.e., the signal S1), the duty ratio of the signal S3 (i.e., the signal S13) inputted to the Gaussian filter 101 can be adjusted. Therefore, the voltage level obtained by having the signal S3 inputted to the Gaussian filter 101 can be adjusted to a desired voltage level (e.g. the midpoint voltage level of the signal S13 (i.e., signal S7)). As a result, it becomes possible to let the frequency that the PLL modulation circuit 110 is supposed to lock at the time when there is no transmission data TXD (i.e., the signal S1) become the target frequency Fc [Hz] that is determined by the voltage level (e.g. the midpoint voltage level) obtained from the signal S13 whose duty ratio was adjusted. Thus, it becomes possible to control the center frequency at the time when there is a status change indicating that there is an input of transmission data TXD (i.e., the signal S1) that will become the target center frequency Fc [Hz]. In other words, according to this embodiment, it is possible to adjust the center frequency of the output signal (i.e., the signal S5) outputted from the PLL modulation circuit 110, i.e., the center frequency of a carrier (i.e., a carrier wave), to the target center frequency Fc [Hz], and generate a transmission waveform having the same modulation width in the positive side and in the negative side. Thereby, it becomes possible to output a modulation wave with higher precision and quality.

### Third Embodiment

Now, a third embodiment of the present invention will be described in detail with reference to the drawings. In the following description, the same reference numbers will be used with respect to the same structural elements as those in the first embodiment or the second embodiment, and a detailed explanation of those structural elements will be omitted.

Structure

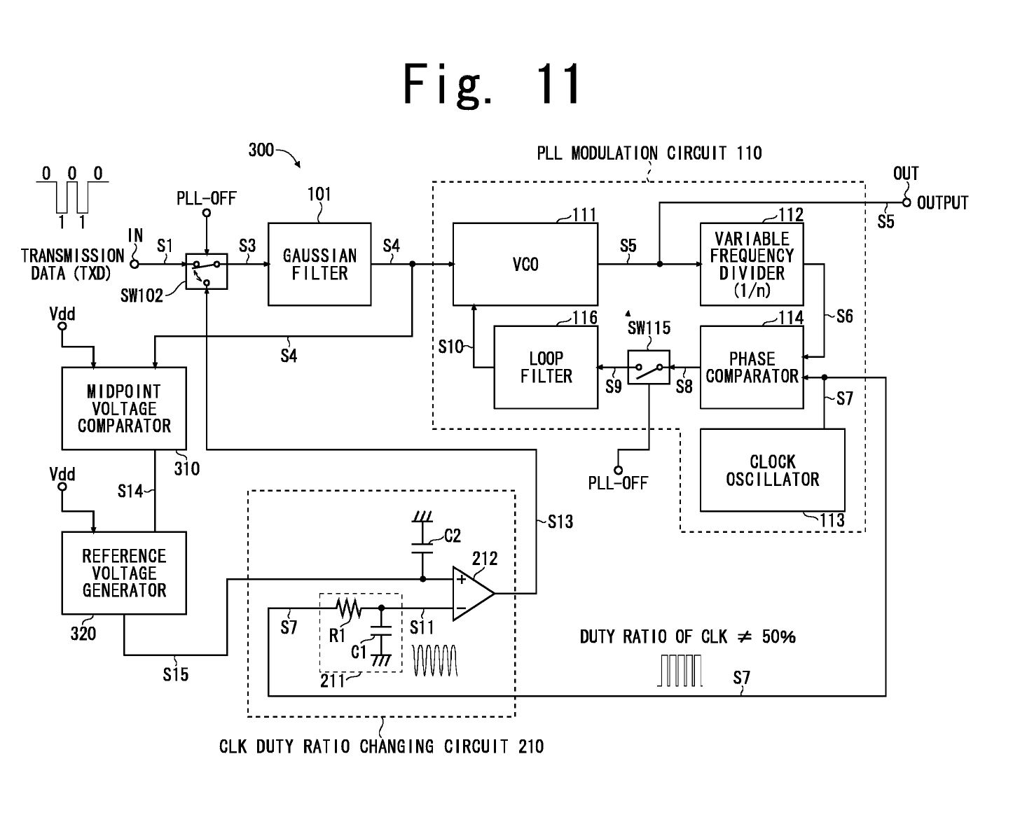

FIG. 11 is a schematic block diagram showing an outline structure of a GFSK radio apparatus 300 according to this embodiment of the present invention.

As can been seen from FIG. 11, the basic structure of the GFSK radio apparatus 300 is the same as the GFSK radio apparatus 200 according to the second embodiment, except that the GFSK radio apparatus 300 has a midpoint voltage comparator 310 and a reference voltage generator 320 added to the basic structure. Moreover, in this embodiment, the variable resistance VR1 in the CLK duty ratio changing circuit 210 is eliminated, and instead, it is arranged such that the output (i.e., the signal S15) from the reference voltage generator 320 will be inputted to the non-inverting input terminal of the comparator 212. Here, the midpoint voltage comparator 310 and the reference voltage generator 320 can also be referred to as a reference voltage output unit.

In the structure shown in FIG. 11, the signal S4 outputted from the Gaussian filter 101 and a power supply voltage Vdd will be inputted to the midpoint voltage comparator 310. The midpoint voltage comparator 310 will then generate a reference voltage (i.e., a reference voltage Vref2/a second reference voltage) having a voltage level for oscillating the VCO 111 at the target center frequency Fc [Hz] based on the inputted power supply voltage Vdd. This reference voltage Vref2 has the same voltage level as the midpoint voltage of the reference clock (i.e., the signal S7) outputted from the reference oscillator 113, and can be generated by voltage-dividing the power supply voltage Vdd using the resistance provided in the midpoint voltage comparator 310, for instance. The midpoint voltage comparator 310 will compare the generated reference voltage Vref2 and the inputted signal S4, and output the voltage difference between the two as a signal S14.

Based on the signal S14 (i.e., the voltage difference) received from the midpoint voltage comparator 310, the reference voltage generator 320 will generate a reference voltage (i.e., a reference voltage Vref3/a first reference voltage) to be inputted to the non-inverting input terminal of the comparator 212 in the CLK duty ratio changing circuit 210, and output the generated reference voltage Vref3 as a signal S15. This reference voltage Vref3 (i.e., the signal S15) can be generated by adding the signal S14 having its voltage level converted based on a predetermined conversion equation, to a reference voltage (i.e., a reference voltage Vref4) having the same voltage level as the midpoint voltage of the reference clock (i.e., the signal S7) outputted from the reference oscillator 113, for instance. Here, the predetermined conversion equation is an equation which is mainly determined by a time constant of the low-pass filter 211, and it is a coefficient for obtaining an adjusting amount of voltage for slicing a sine wave passed through the low-pass filter 211 by a desired duty ratio (e.g. 50%) based on the signal S14 (i.e., the voltage difference). The reference voltage Vref4 can also be generated by voltage-dividing the power supply voltage Vdd using a resistance provided in the reference voltage generator 320, for instance, in the same way as the reference voltage Vref2.

The reference voltage Vref3 generated in the above-described manner will be inputted to the non-inverting input terminal of the comparator 212 in the CLK duty ratio changing circuit 210 as the signal S15, as mentioned above. Accordingly, the comparator 212 will generate the signal S13 which is in the form of a rectangular wave and has a duty ratio of 50% by slicing the inputted signal S11 by the signal S15, i.e., the reference voltage Vref3, and output the generated signal S13 to the switch SW 102.

The rest of the structure of the GFSK radio apparatus 300 is the same as the GFSK radio apparatus 100 according to the first embodiment or the GFSK radio apparatus 200 according to the second embodiment, and therefore, a detailed description thereof will be omitted here.

Operation

Now, an operation of the GFSK radio apparatus 300 according to the third embodiment of the present invention will be described. The basic operation of the GFSK radio apparatus 300 is the same as in the case of the second embodiment. Accordingly, only the operation of generating the signal S15 (i.e., the reference voltage Vref3) will be described here.

Operation of Generating Signal S15 (i.e., Reference Signal Vref3)

As described above, the reference voltage Vref3 (i.e., the signal S15) is generated by comparing the signal S4 branched from the Gaussian filter 101 and the reference voltage Vref2 generated from the power supply voltage Vdd, converting the resultant signal indicating the voltage difference based on a predetermined conversion coefficient, and adding it to the reference voltage Vref4 generated from the power supply voltage Vdd.

To be more precise, first, the signal S4 will be inputted to the midpoint voltage comparator 310 shown in FIG. 11. The power supply voltage Vdd will also be inputted to the midpoint voltage comparator 310. The midpoint voltage comparator 310 will then generate the reference voltage Vref2 based on the inputted power supply voltage Vdd. As mentioned earlier, this reference voltage Vref2 is a signal having a voltage level for oscillating the VCO 111 at the target center frequency Fc [Hz]. The midpoint voltage comparator 310 will compare the reference voltage Vref2 and the inputted signal S4, and output a voltage difference between the two as the signal S114 to the reference voltage generator 320.

To the reference voltage generator 320, the power supply voltage Vdd will also be inputted. The reference voltage generator 320 will then generate the reference voltage Vref4 based on the inputted power supply voltage Vdd. Moreover, the reference voltage generator 320 will multiply the inputted signal S14 by a predetermined conversion coefficient, add the result to the generated reference voltage Vref4 to generate the reference voltage Vref3 (i.e., the signal S15) for slicing a since wave outputted from the low-pass filter 211 in the CLK duty ratio changing circuit 210, and output the reference voltage Vref3 to the non-inverting input terminal of the comparator 212 in the CLK duty ratio changing circuit 210.

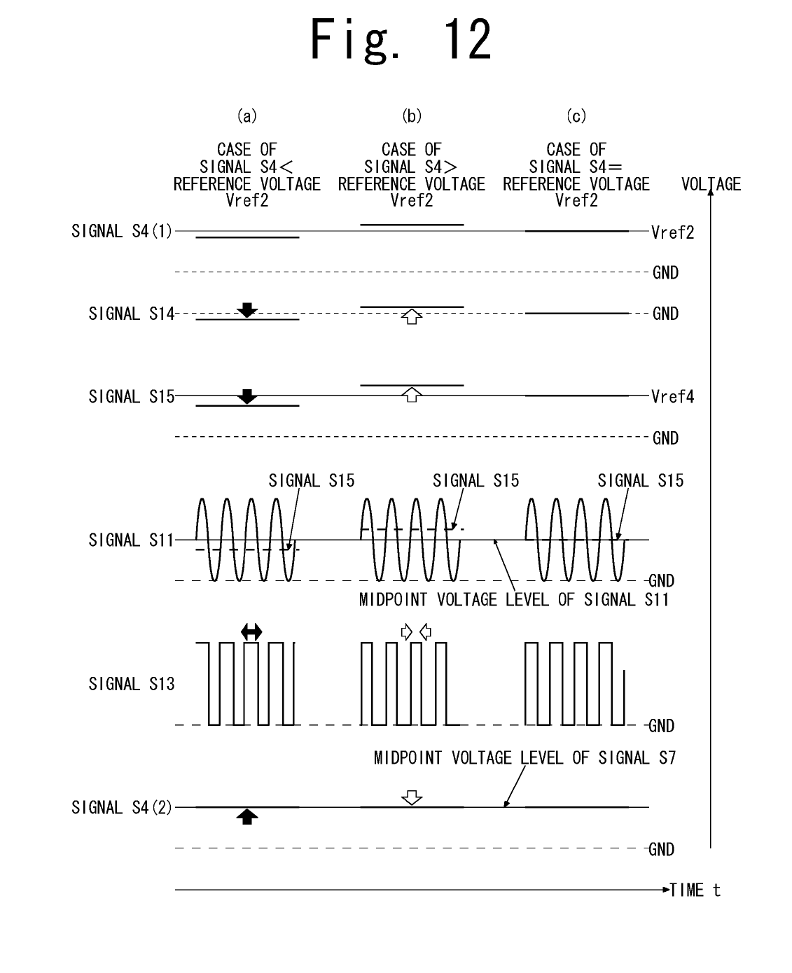

The flow of the operation for generating the reference voltage Vref3 (i.e., the signal S15) mentioned above will be described with reference to FIG. 12.

First, as shown by the status illustration ‘signal S4 (1)’ in column 12(a), when the voltage level of the signal S4 is lower than the reference voltage Vref2, the midpoint voltage comparator 310 will output a negative voltage difference, which is obtained by subtracting the reference voltage Vref2 from the signal S4, as the signal S114 as shown by the status illustration ‘signal S14’ in column 12(a). The signal S14 will be multiplied by a predetermined conversion coefficient at the reference voltage generator 320 and then added to the reference voltage Vref4. Thereby, as shown by the status illustration ‘signal S15’ in column 12(a), the signal S15 (i.e., the reference voltage Vref3) having a voltage level which is lower than the reference voltage Vref4, i.e., the voltage level which is lower than the midpoint voltage of the reference clock (i.e., the signal S7), will be generated. Therefore, in the CLK duty ratio changing circuit 210, the signal S11 will be sliced at the lower side of the midpoint voltage level of the signal S11, as shown by the status illustration ‘signal S11’ in column 12(a). As a result, as shown by the status illustration ‘signal S13’ in column 12(a), the signal S13 having its duty ratio adjusted to become high will be outputted from the comparator 212. Accordingly, as shown by the status illustration ‘signal S4(2)’ in column 12(a), the voltage level of the signal S4 outputted from the Gaussian filter 101 will be adjusted to a voltage level for oscillating the VCO 111 at the target center frequency Fc [Hz], i.e., to the midpoint voltage level of the signal S7.

Now, as shown by the status illustration ‘signal S4(1)’ in column 12(b), when the voltage level of the signal S4 is higher than the reference voltage Vref2, the midpoint voltage comparator 310 will output a positive voltage difference, which is obtained by subtracting the reference voltage Vref2 from the signal S4, as the signal S14 as shown by the status illustration ‘signal S14’ in column 12(b). The signal S14 will be multiplied by a predetermined conversion coefficient at the reference voltage generator 320, and then added to the reference voltage Vref4. Thereby, as shown by the status illustration ‘signal S15’ in column 12(b), the signal S15 (i.e., the reference voltage Vref3) having a voltage level which is higher than the reference voltage Vref4, i.e., a voltage level which is higher than the midpoint voltage of the reference clock (i.e., the signal S7), will be generated. Therefore, in the CLK duty ratio changing circuit 210, the signal S11 will be sliced at the upper side of the midpoint voltage level of the signal S11, as shown by the status illustration ‘signal S11’ in column 12(b). As a result, as shown by the status illustration ‘signal S13’ in column 12(b), the signal S13 having its duty ratio adjusted to become low will be outputted from the comparator 212. Accordingly, as shown by the status illustration ‘signal S4(2)’ in column 12(b), the voltage level of the signal S4 outputted from the Gaussian filter 101 will be adjusted to a voltage level for oscillating the VCO 111 at the target center frequency Fc [Hz], i.e., to the midpoint voltage level of the signal S7.

Furthermore, as shown by the status illustration ‘signal S4(1)’ in column 12(c), when the voltage level of the signal S4 is equal to the reference voltage Vref2, the midpoint voltage comparator 310 will output a signal at a ground level as the signal S14, as shown by the status illustration ‘signal S14’ in column 12(c). Thereby, as shown by the status illustration ‘signal S15’ in column 12(c), the reference voltage Vref4 will be outputted as is from the reference voltage generator 320 as the signal S15 (i.e., the reference voltage Vref3). Therefore, in the CLK duty ratio changing circuit 210, the signal S11 will be sliced at a midpoint voltage level of the signal S11, as shown by the status illustration ‘signal S11’ in column 12(c). As a result, as shown by the status illustration ‘signal S13’ in column 12(c), the signal S13 having its duty ratio unchanged will be outputted from the comparator 212. Accordingly, as shown by the status illustration ‘signal S4(2)’ in column 12(c), the voltage level of the signal S4 outputted from the Gaussian filter 101 will be unchanged.

As described above, in addition to the effects achieved by the second embodiment, the third embodiment of the present invention allows for enabling the duty ratio of the signal S13 inputted to the Gaussian filter 101 to be automatically adjusted when there is no input of transmission data TXD. Accordingly, according to the third embodiment of the present invention, it is possible to automatically generate a modulation wave with higher precision and quality. In other words, when the duty ratio of the reference clock (i.e., the signal S7) is not a desired duty ratio (e.g. 50%), it is possible to automatically adjust the center frequency of the output signal (i.e., the signal S5), i.e., the center frequency of a carrier (i.e., a carrier wave), to the target center frequency Fc [Hz], and generate a transmission waveform having the same modulation width in the positive side and in the negative side.

While the preferred embodiments of the invention have been described using specific terms, such description is for illustrative purposes only, and it is to be understood that changes and variations may be made without departing from the spirit or the scope of the following claims.

This application claims priority to Japanese Patent Application No. 2005-186033. The entire disclosures of Japanese Patent Application No. 2005-186033 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

1. A radio apparatus comprising:
a PLL modulator configured to output a signal whose frequency is modulated based on a voltage level of an input signal;
a first switch to which a first signal having a predetermined frequency and a second signal are inputted, the first switch configured to allow one of the first and second signals to pass therethrough based upon the presence of the second signal;
a first filter configured to smooth the first or second signal that has passed through the first switch, and output the smoothed first or second signal to the PLL modulator; and
a second switch configured to break a loop in the PLL modulator based on the presence of the second signal.

2. A radio apparatus comprising:
a PLL modulator configured to output a signal whose frequency is modulated based on a voltage level of an input signal;
a duty ratio changing unit configured to adjust a duty ratio of a first signal having a predetermined frequency;
a first switch to which the first signal having the adjusted duty ratio and a second signal are inputted, the first switch configured to allow one of the first and second signals pass through based on the presence of the second signal;
a first filter configured to smooth the first or second signal that has passed through the first switch, and output the smoothed first or second signal to the PLL modulator; and
a second switch configured to break a loop in the PLL modulator based on the presence of the second signal.

3. The radio apparatus according to claim 2, wherein
the duty ratio changing unit comprises:
a second filter configured to transform the first signal to a sine wave or an approximate sine wave,
a reference voltage generator configured to output a first adjustable reference voltage, and
a comparator configured to output a first voltage when the voltage level of the first signal transformed to the sine wave or the approximate sine wave is higher than the first reference voltage, and output a second voltage when the voltage level of the first signal transformed to the sine wave or the approximate sine wave is lower than the first reference voltage.

4. The radio apparatus according to claim 3, wherein
the reference voltage generator has a variable resistance, and adjusts the voltage level of the first reference voltage based on the resistance value of the variable resistance.

5. The radio apparatus according to claim 3, wherein
the reference voltage generator is configured to generate the first reference voltage based on a comparison between the second reference voltage and the smoothed first signal having the adjusted duty ratio or the smoothed second signal.

6. The radio apparatus according to claim 1, wherein
the PLL modulator comprises:
a reference oscillator configured to output the first signal,
a voltage controlled oscillator configured to output a third signal having a frequency that is based on a voltage of an inputted signal,
a divider configured to divide the third signal outputted from the voltage controlled oscillator by a predetermined dividing ratio,
a phase comparator configured to output a fourth signal based on a phase difference between the divided third signal and the first signal, and
a second filter configured to smooth the fourth signal outputted from the phase comparator,
the smoothed first or second signal and the smoothed fourth signal are inputted to the voltage controlled oscillator, and
the voltage controlled oscillator oscillates based on the smoothed first or second signal and the smoothed fourth signal.

7. The radio apparatus according to claim 2,
the PLL modulator comprises:
a reference oscillator configured to output the first signal,
a voltage controlled oscillator configured to output a third signal having a frequency based on an voltage of an inputted signal,
a divider configured to divide the third signal outputted from the voltage controlled oscillator by a predetermined dividing ratio,
a phase comparator configured to output a fourth signal based on a phase difference between the divided third signal and the first signal, and
a third filter configured to smooth the fourth signal outputted from the phase comparator,
wherein the smoothed first signal having the adjusted duty ratio, or the smoothed second signal and the smoothed fourth signal, are inputted to the voltage controlled oscillator, and
the voltage controlled oscillator oscillates based on the smoothed first signal having the adjusted duty ratio, or the smoothed second signal and the smoothed fourth signal.

8. The radio apparatus according to claim 7, wherein
the second filter is a low-pass filter.

9. The radio apparatus according to claim 6, wherein
the second switch is electrically connected between the divider and the voltage controlled oscillator.

10. The radio apparatus according to claim 7, wherein
the second switch is electrically connected between the divider and the voltage controlled oscillator.

11. The radio apparatus according to claim 1, wherein
the divider is a variable divider.

11. (canceled)

12. The radio apparatus according to claim 1, wherein
the first filter is a Gaussian filter.

13. The radio apparatus according to claim 2, wherein
the first filter is a Gaussian filter.

14. The radio apparatus according to claim 2, wherein the divider is a variable divider.
